(19) United States
(12) Patent Application Publication
(10) Pub. No.: US 2025/0261461 A1
(43) Pub. Date: Aug. 14, 2025

(54) OPTICAL DEVICE

(71) Applicant: STMicroelectronics International N.V., Geneva (CH)

(72) Inventor: Laurent-Luc CHAPELON, Domene (FR)

(73) Assignee: STMicroelectronics International N.V., Geneva (CH)

(21) Appl. No.: 19/048,105

(22) Filed: Feb. 7, 2025

(30) Foreign Application Priority Data
Feb. 13, 2024 (FR) FR2401385

(51) Int. Cl. H10F 39/00

(52) U.S. Cl. CPC H10F 39/804; H10F 39/024; H10F 39/8063; H10F 39/811

(57) ABSTRACT

An optical device, such as an imager, successively comprises the following structures: a support in which vias are formed; a first electrode; an active layer capable of absorbing photons and transforming them into electron-hole pairs; a second electrode; a conductive layer connecting the second electrode to one of the vias; and a microlens matrix. The device further includes an encapsulation layer arranged between the microlens matrix and the active layer. The encapsulation layer has a first portion with a first density and a second portion with a second density. The first portion of the encapsulation layer is arranged between the active layer and the second portion of the encapsulation layer. The first density is lower than the second density.

### PRIORITY CLAIM

This application claims the priority benefit of French Application for Patent No. 2401385, filed on Feb. 13, 2024, the content of which is hereby incorporated by reference in its entirety to the maximum extent allowable by law.

### TECHNICAL FIELD

The present description relates generally to optical devices, such as image acquisition devices or image sensors. More particularly, the present description relates to an optical device comprising pixels and microlenses.

### BACKGROUND

An optical device, such as an imager, comprises microlenses that focus light onto an active layer (also known as a quantum film (QF)) capable of transforming photons into electron-hole pairs. An anti-reflective layer is placed between the microlenses and the active layer. The anti-reflective layer also acts as a protective layer for the active layer.

A top electrode, for collecting holes, and a bottom electrode, for collecting electrons, are arranged on either side of the active layer. The top electrode makes contact with the upper part of the active layer and is offset to vias positioned in the substrate (referred as a Build in Pad (BIP)) by means of a conductive layer, made of aluminum for example. To enable contact to be made on the second electrode (referred to as a Contact on PhotoDiode (CTPD)), an opening is formed in the anti-reflective layer.

So, when the image-acquisition device is exposed to radiation of a suitable wavelength (e.g., Short-Wave InfraRed (SWIR)), the photons pass through the microlenses and the anti-reflective layer and penetrate the active layer. Electrons and holes are then generated. The electrons are directed and guided by vias to the nodes of the device (in other words, to the active areas of the circuit). Holes are collected by the top electrode and directed through the conductive layer to the vias (BIPs).

In order to guarantee the reliability of the electronic components and achieve a quantum efficiency (QE) of the active layer of over 50%, the optical device has to meet a number of criteria: resistance to temperature, humidity and so on.

However, in current optical devices, oxidation of the active layer can occur as a result of its circuit manufacturing processes or reliability tests (exposure to humidity).

On the one hand, it has been observed that current anti-reflective coatings are not sufficiently effective in preventing oxidation of the active layer.

On the other hand, the conductive aluminum layer enabling contact to be made may have defects, in particular pitting, resulting from its manufacturing process. These defects are responsible for creating a certain permeability in the aluminum layer, which can lead to problems during structuring, particularly by wet etching. Indeed, the chemicals used to clean the photolithography resin can penetrate the aluminum layer and contaminate the active layer, particularly in the region of the second electrode makes contact (for example, to the Contact on PhotoDiode (CTPD)).

Bringing the active layer into contact with air, water and/or other oxidizing agents leads to a reduction in its performance, and it may be difficult or even impossible to achieve an active layer quantum efficiency greater than 50%.

There is a need to improve the performance of optical devices, and in particular to prevent oxidation of the active layer.

### SUMMARY

Improvement is achieved by an optical device, such as an imager, successively comprising: a support in which vias are formed; a first electrode; an active layer capable of absorbing photons and transforming them into electron-hole pairs; a second electrode; a conductive layer connecting the second electrode to one of the vias; and a microlens matrix. The device further comprises: an encapsulation layer arranged between the microlens matrix and the active layer, the encapsulation layer comprising a first portion having a first density and a second portion having a second density, the first portion of the encapsulation layer being arranged between the active layer and the second portion of the encapsulation layer, the first density being lower than the second density.

According to an embodiment, the encapsulation layer is based on silicon oxide.

According to an embodiment, the encapsulation layer is arranged between the active layer and the conductive layer.

According to an embodiment, the encapsulation layer covers the sides and a part of an upper face of the active layer.

According to an embodiment, the encapsulation layer is arranged between and in contact with two metal nitride layers, preferably in silicon nitride.

According to an embodiment, the encapsulation layer is arranged between the conductive layer and the microlens matrix.

According to an embodiment, the encapsulation layer is covered by a metal nitride layer, preferably silicon nitride.

According to an embodiment, the device comprises two encapsulation layers, one of the encapsulation layers being arranged between the active layer and the conductive layer and the other of the encapsulation layers being arranged between the conductive layer and the microlens matrix.

According to an embodiment, the conductive layer is made of aluminum.

According to an embodiment, the first density is between 2.05 g/cm³ and 2.13 g/cm³, for example 2.09 g/cm³, and/or the second density is between 2.20 g/cm³ and 2.28 g/cm³, for example 2.24 g/cm³.

According to an embodiment, the first portion of the encapsulation layer has a thickness of between 50 and 250 nm and/or wherein the second portion of the encapsulation layer has a thickness of between 3 and 50 nm.

This is also achieved by a method of manufacturing an optical device according to the present invention. The method comprises forming an encapsulation layer according to the following steps: depositing a first precursor at a first deposition rate to form a first portion of the encapsulation layer having a first density; depositing a second precursor at a second deposition rate to form a second portion of the encapsulation layer having a second density; the first deposition rate being greater than the second deposition rate, whereby the first density is less than the second density.

According to an embodiment, the first portion of the encapsulation layer and the second portion of the encapsulation layer are deposited by PECVD at a temperature less than or equal to 150° C.

According to an embodiment, the first precursor and the second precursor are silicon oxide precursors, the first precursor and the second precursor being preferably silicon alkoxides, more preferably TEOS.

According to an embodiment, the first deposition rate is at least 5 times greater than the second deposition rate.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A shows a schematic cross-section of an optical device;

FIG. 1B shows a schematic cross-section of an optical device;

FIG. 1C shows a schematic cross-section of an optical device;

FIG. 2 is a graph showing the variation in water (in mg) as a function of time for different layers: a SiON layer annealed at 300° C., a SiON layer annealed at 400° C., a 100 nm thick SiO₂ layer deposited at low speed from TEOS (referred to as the TEOS Low Deposition Rate (TEOS LDR)) and annealed at 400° C., a 142 nm thick SiO₂ layer and a 200 nm thick SiO₂ layer deposited by PECVD;

FIG. 3 is a graph showing tensile stress as a function of time for an SiO₂ layer;

FIG. 4 is a graph showing the variation in compressive stress as a function of time for a layer of SiON;

FIG. 5 is a scanning electron microscope (SEM) image of a part of an active layer, one side of which is successively covered by a SiN layer and then by an SiO₂ layer; and

FIG. 6 is a transmission electron microscope (TEM-EDX) image of the BIP region of an optical device.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Unless otherwise specified, between X and Y values means that the terminal values X and Y are included in the range.

In the rest of the description, unless otherwise specified, a layer or film is said to be opaque to radiation when the transmittance of the radiation through the layer or film is less than 30%, and preferably less than 10%.

In the rest of the description, a layer or film is said to be transparent to radiation when the transmittance of the radiation through the layer or film is greater than 50%, and preferably greater than 70%.

Optical device embodiments will now be described for optical devices comprising an array of micrometer-sized optical elements, where each micrometer-sized optical element corresponds to a micrometer-sized lens, or microlens, composed of two diopters. However, it is clear that these embodiments can also be implemented with other types of micrometer-sized optical elements, with each micrometer-sized optical element corresponding, for example, to a micrometer-sized Fresnel lens, a micrometer-sized gradient-index lens or a micrometer-sized diffraction grating.

The optical device can be an image acquisition device operating in the near infrared (NIR), i.e., for electromagnetic radiation with a wavelength between 800 nm and 2500 nm, and more particularly in the short infrared (SWIR), i.e., for electromagnetic radiation with a wavelength between 800 nm and 2000 nm, preferably between 900 nm and 1700 nm, typically 1.4 μm.

The optical device can be an optical sensor, in particular a proximity sensor.

This is a device with photodiodes arranged above the integrated circuit (referred to as a Photodiode Above IC arrangement).

The optical device is of interest for a wide range of applications, including the automotive market (fog sensors, for example) and telephony (smartphones).

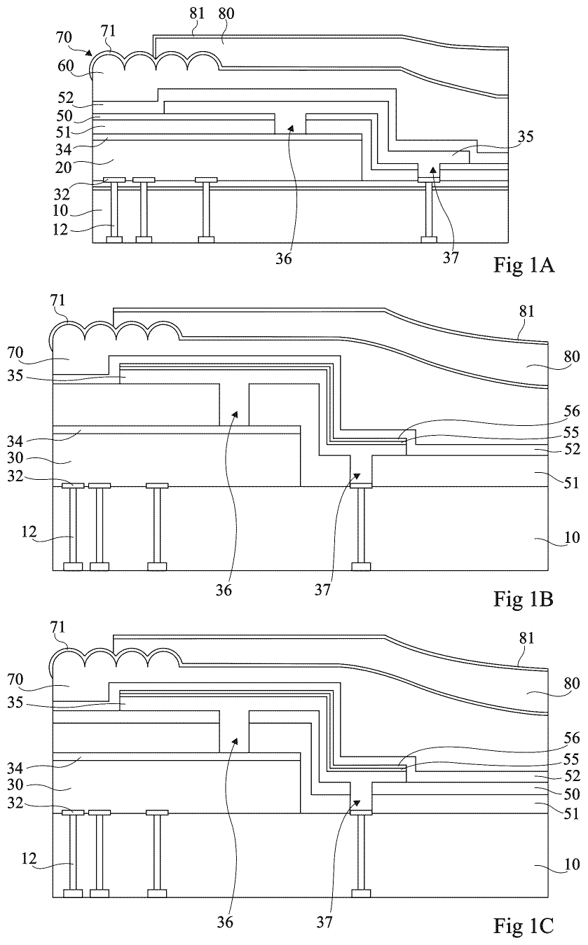

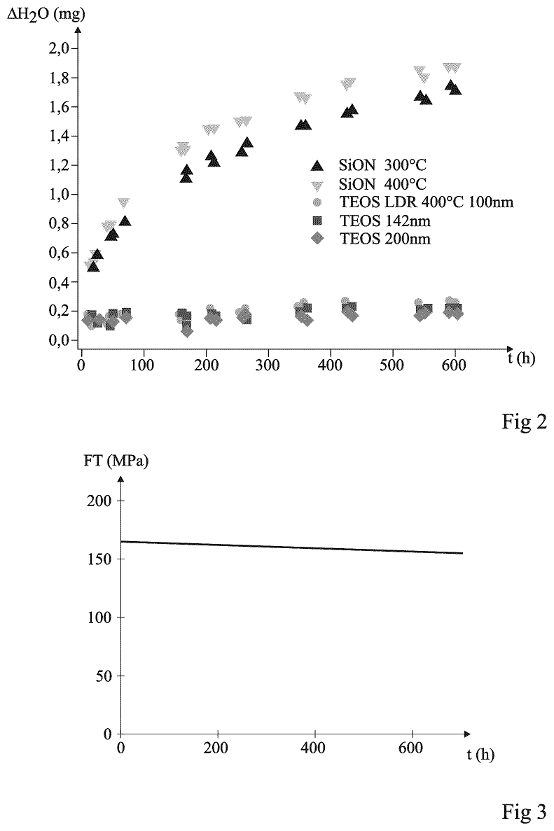

We will now describe the image acquisition system in more detail, with reference to FIG. 1A, FIG. 1B and FIG. 1C.

The device comprises a support 10 in which vias 12 are formed. The vias 12 are filled with a conductive material, such as copper. The support 10 may comprise a stack of insulating layers (not shown) and conductive tracks (not shown) between the insulating layers. The stack is preferably around 2 μm thick. Vias 12 can be 3.2 μm deep.

The substrate 10 is covered by an active layer 20. Active layer 20 transforms photons received from the top of the device into electron/hole pairs.

The active layer 20 comprises a first face (bottom face), partially in contact with the substrate 10, a second face (top face) and flanks.

The active layer 20 is preferably made of a semiconductor material, such as silicon.

Electronic components are formed under the vias (‘Viatop’). These may be insulated-gate field-effect transistors, or MOS transistors (‘Metal Oxide Semiconductor’), in particular made using CMOS technology (‘Complementary Metal Oxide Semiconductor’) and/or photodetectors.

The active layer 20 has, for example, a thickness of the order from 0.4 μm to 1 μm.

The active layer 20 is arranged between a first electrode 32 and a second electrode 34.

The first electrode 32, for example, collects electrons. The second electrode 34, for example, collects holes.

The first electrode 32 (or bottom electrode) is in contact with the first face of the active layer 20 and with the substrate 10.

The first electrode 32 is, for example, metallic.

The first electrode 32 is, for example, in the form of conductive studs.

The first electrode 32 is connected to the vias 12 of the substrate 10.

The second electrode 34 (or top electrode) preferably completely covers the second side of the active layer 20.

The second electrode 34 is, for example, a bilayer or a triple-layer (or trilayer) structure. The second electrode 34 has a thickness of from 40 to 60 nm for example.

The second electrode 34 is connected to one of the vias 12 positioned in the substrate 10 (referred to as Built in Pad (BIP)) via a conductive layer 35 which allows the contact to be offset.

The conductive layer makes contact with the second electrode 34 in the region known as the Contact on PhotoDiode (CTPD).

To enable contact to be made on the second electrode (Contact on PhotoDiode (CTPD)), an opening is formed in an anti-reflective coating covering the second electrode 34.

As we shall see later, the anti-reflective coating can also act as a protective layer for the active layer 20.

The device also includes a planarization layer 60 covering the anti-reflective coating. Preferably, this is a resin layer.

An array of micrometer-sized lenses 70 (or microlens matrix) covers the planarization layer 60. The lenses are, for example, formed of elements having a convex plane and a planar face. The flat face of the microlenses preferably rests on the top face of the resin layer and is in contact with the resin layer.

The array of 70 microlenses focuses the radiation on the pixels.

The array of microlenses 70 is preferably arranged in a matrix form, with the optical axis of each microlens coinciding with the center of a resin block. The microlenses are, for example, composed of an organic resin. The microlenses are preferably transparent in the wavelengths under consideration.

In one embodiment, the microlenses are all the same, i.e., they have the same chemical composition and the same dimensions. Alternatively, the microlenses may not all have the same dimensions.

The device can include a protective layer 71 covering the microlenses 70. The protective layer 71 can be made of an inorganic material, for example a silicon oxide (SiO₂) or a silicon oxynitride (SiON). In one embodiment, the protective layer is substantially impervious to moisture. For example, the protective layer has a thickness of between 100 nm and 600 nm.

The device can include a layer of resin 80, known as black resin, which strongly absorbs incident light in the wavelengths of interest. Black resin 80 is also known as a LOgical light BlOcking (LOBO) resin. Black resin 80 covers part of the microlens, while the other part is not covered by black resin. The resin layer 80 can be protected by a protective layer 81. The protective layer 81 can be made of an inorganic material, for example a silicon oxide (SiO₂) or a silicon oxynitride (SiON). In one embodiment, the protective layer is substantially impervious to moisture. For example, the protective layer has a thickness of between 100 nm and 600 nm.

The device also includes at least one encapsulation layer 50, 55 arranged between the active layer 20 and the microlens matrix 70. The encapsulation layer 50, 55 may be a layer of SiO₂ or SiON. Preferably, the encapsulation layer 50, 55 is made of SiO₂. Typically, each encapsulation layer 50, 55 is made of a single (dielectric) material.

Each encapsulation layer 50, 55 comprises two parts (or portions): a first part (lower part) with a first density and a second part (upper part) with a second density. The respective first and second parts are made of the same (dielectric) material since they form part of the encapsulation material itself. The first part is arranged between the active layer and the second part. In other words, the first part is arranged on the lower side of the device, opposite the active layer 20, and the second part on the upper side of the device, opposite the microlens matrix 70.

The first density is lower than the second density.

For example, the first density (i.e., the density of the lower part) is between 2.05 g/cm³ and 2.13 g/cm³ and/or the second density (i.e., the density of the upper part) is between 2.20 g/cm³ and 2.28 g/cm³. For example, for an encapsulation layer made of SiO₂, the first density can be 2.09 g/cm³ and/or the second density can be 2.24 g/cm³.

The upper part forms a dense layer (or crust) encapsulating the lower part of the layer.

The second part has a thickness of, for example, between 3 and 50 nm, preferably between 10 and 50 nm, and even more preferably between 10 and 30 nm, for example of the order of 20 nm.

The thickness of the first part is greater than the thickness of the second part. The thickness of the first part is, for example, between 50 and 250 nm, preferably between 150 and 250 nm, even more preferably between 180 and 230 nm, for example of the order of 210 nm.

The first part, for example, has a refractive index of between 1.43 and 1.45 (for a wavelength of 633 nm). The second part, for example, has a refractive index of between 1.47 and 1.48 (for a wavelength of 633 nm).

In the first implementation shown in FIG. 1A, the encapsulation layer 50 is positioned between the active layer 20 and the conductive contact layer 35.

The encapsulation layer 50 covers the top electrode 34 and the active layer 20, and protects the sides of the active layer 20. It can also cover part of the substrate 10.

In this first implementation, the encapsulation layer 50 also acts as an anti-reflective layer.

In a second implementation as shown in FIG. 1B, the encapsulation layer 55 is positioned between the conductive contact layer 35 and the microlens matrix 70. More specifically, it is in contact with the conductive layer 35. Preferably, it completely covers the conductive layer 35. This protects not only the PTCD zone but also the BIP zone.

In a third implementation as shown in FIG. 1C, the device may comprise both the encapsulation layers 50, 55: a first encapsulation layer 50 is positioned between the active layer 20 and the conductive layer 35, and a second encapsulation layer 55 is positioned between the conductive layer 35 and the microlens matrix 70.

The device may further comprise one or more metal nitride layers 51, 52, 56. For example, the encapsulation layer 50 may be interposed between two metal nitride layers (e.g., layers 51 and 52 as shown in FIGS. 1A and 1C), and encapsulation layer 55 may be overlapped by one metal nitride layer (e.g., layer 56 as shown in FIGS. 1B and 1C). The assembly encapsulation layer and metal nitride layer/s form an encapsulation element.

The metal nitride is preferably a silicon nitride. Each metal nitride layer 51, 52, 56 has, for example, a thickness of between 300 and 400 nm, preferably between 350 nm and 380 nm.

In particular, the encapsulation element can be a bilayer (e.g., SiO₂/SiN) or a triple-layer (SiN/SiO₂/SiN). A bilayer will advantageously be used when the encapsulation layer is between the conductive layer 35 and the microlens matrix 70. A triple-layer is advantageously used when the encapsulation layer is between the active layer 20 and the conductive layer 35. The triple-layer can act not only as an encapsulation element, but also as an anti-reflective element.

The encapsulation element has, for example, a total thickness of between 30 nm and 200 nm, preferably between 40 nm and 130 nm, more preferably around 40 nm. The thickness of the resulting encapsulation element (bilayer or triple-layer) will depend in particular on its position. The thickness of the encapsulation element is, advantageously, adapted so that the layer is transparent in the visible range.

In particular, we will describe the manufacturing process of the encapsulation layer 50, 55 of the device.

The encapsulation layer 50, 55 is formed according to the following steps: deposition of the first portion of the encapsulation layer 50, 55; deposition of the second portion of the encapsulation layer 50, 55 on the first portion of the encapsulation layer 50, 55.

The first portion of the encapsulation layer 50, 55 and the second portion of the encapsulation layer 50, 55 are preferably deposited using a plasma-assisted chemical vapor deposition (PECVD) technique.

To form each encapsulation layer 50, 55 with different densities, the respective first and second parts of the encapsulation layers are formed at different deposition rates.

The first part is formed at a first deposition rate and the second part is formed at a second deposition rate. The first deposition rate is higher than the second deposition rate. The first deposition rate is at least 5 times greater than the second deposition rate. It is, for example, about 10 times greater than the second deposition rate.

In PECVD deposition, for example, it is possible to modify the deposition rate by adjusting one or more of the following parameters: the power of the high frequency, the use of a low frequency (in addition to the high frequency) and/or the heating temperature.

A first precursor may be used to form the first part of both the encapsulation layer 50, 55 and a second precursor may be used to form the second part of both the encapsulation layer 50, 55. Preferably, the same precursor is used to deposit the first part and the second part of the encapsulation layer 50, 55.

The encapsulation layer 50, 55 is preferably deposited at a temperature of 150° C. or less. Advantageously, it is carried out at a temperature above 100° C. Even more preferably, it is carried out at a temperature of between 120° C. and 150° C.

The layer 50, 55 deposited in this way has very good conformability, which ensures better protection of the underlying pixel, particularly in terms of sealing. Oxidation phenomena are thus avoided.

Preferably, the encapsulation layer 50, 55 is made of SiO₂ and the precursors are silicon oxide precursors, such as silicon alkoxides.

The first part of the silicon oxide encapsulation layer 50, 55 may be deposited from a plasma comprising a first silicon alkoxide. Preferably, it is deposited from a plasma comprising the first silicon alkoxide, oxygen and helium.

The second part of the silicon oxide encapsulation layer 50, 55 may be deposited from a plasma comprising a second silicon alkoxide. Preferably, it is deposited from a plasma comprising the second silicon alkoxide, oxygen and helium.

The first and second silicon alkoxide are preferably a silicon alkoxide with all hydrolyzable functions. The use of a compound with hydrolyzable functions results in a layer made of silicon oxide. In particular, the silicon alkoxide has the formula (R₁O)(R₂O)Si(OR₃)(OR₄) with R₁, R₂, R₃ and R₄ linear alkyl chains, preferably C₁ to C₅ linear alkyl chains. Preferably R₁, R₂, R₃ and R₄ are identical.

The first and second silicon alkoxide are preferably identical. The first and second silicon alkoxides are preferably tetraethyl orthosilicate (TEOS).

The other layers of the encapsulation element can be deposited by chemical vapor deposition (CVD), such as low-pressure chemical vapor deposition (LPCVD), physical vapor deposition (PVD), atomic layer deposition (ALD) or PECVD.

The various layers of the encapsulation element are preferably deposited at a temperature of 150° C. or less.

Layers are formed on the entire plate, i.e., on the entire structure.

A description is now provided of illustrative and non-limiting examples of embodiments.

In order to demonstrate the performance improvement resulting from the presence of the encapsulation layer 50, 55 within an optical device, comparative humidity and/or temperature resistance tests were carried out on different devices or structures.

In a first test, the water-tightness of different layers was tested: SiON layers annealed at 300° C. and 400° C., a SiO₂ layer obtained from TEOS LDR (TEOS Low Deposition Rate) and annealed at 400° C., two SiO₂ layers of 142 nm and 200 nm, obtained from TEOS deposited by PECVD. In each case, the layer is formed on a silicon substrate. The curves clearly show that the SiON layers are permeable to water, whereas the SiO₂ layers are hermetically sealed (FIG. 3). There is no significant water uptake for SiO₂ layers, even after 600 hours, unlike SiON layers.

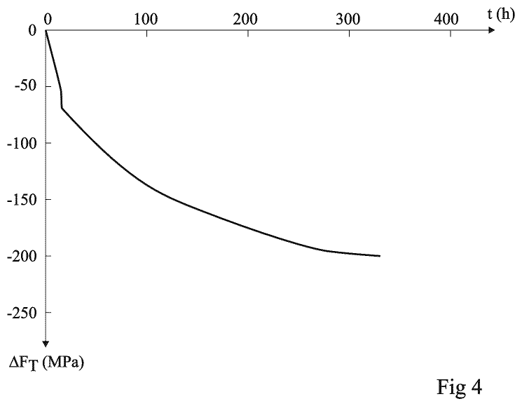

Mechanical tests were also carried out on SiO₂ layers, obtained by PECVD deposition of TEOS (FIG. 3), and on SiON layers annealed at 150° C. (FIG. 4).

The values were obtained from Stoney's formula, which establishes a relationship between radius of curvature, stress and layer and substrate thicknesses.

As the SiO₂ layers are completely watertight, there is no water absorption and therefore no significant stress variation after 600 h, unlike the SiON layer.

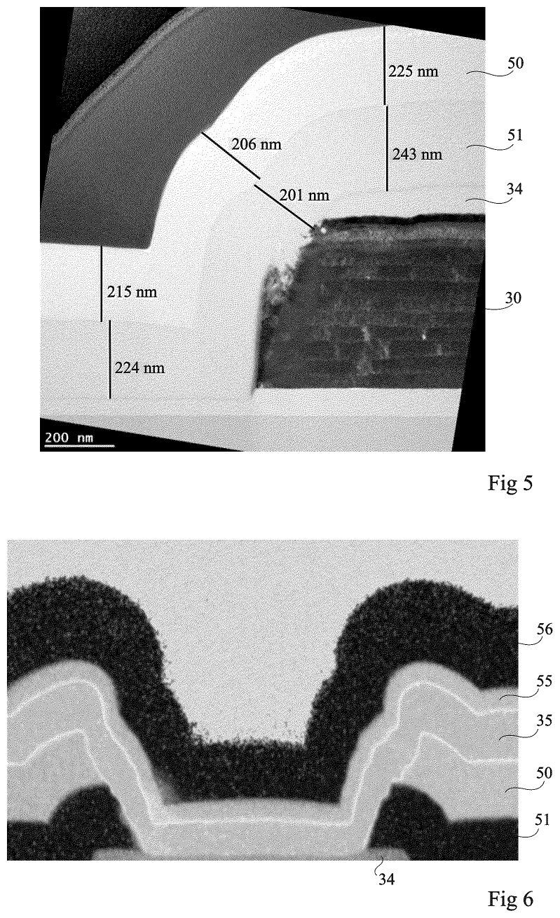

FIG. 5 shows an SEM image of a device on which the first layers of the anti-reflective element have been deposited: a SiN layer and a SiO₂ layer obtained by PECVD deposition of TEOS at 150° C. The deposition is consistent: the thickness on the sides and on the electrode varies by less than 10%. The SiO₂ layer provides uniform protection at all points: not only is the top of the structure protected, but also the sides.

To test their resistance to heat and humidity, two devices were subjected to the Highly Accelerated Stress Test (HAST). One of the devices has a SiN/SiON/SiN anti-reflective element and the other device has a SiN/SiO₂/SiN anti-reflective element in a particular embodiment. The HAST test involved exposing the devices to a temperature of around 110° C. and a relative humidity of 85% for 60 hours and 144 hours in a pressurized enclosure at 2 atm. The devices were then subjected to several characterizations. The device with a SiN/SiO₂/SiN anti-reflective element showed better BIP resistance, better post-lithography BIP definition, better dark current and better mechanical stability.

Finally, the BIP region of a device obtained according to a particular embodiment was observed by MET-EDX. The metal layer 35 made of aluminum is covered successively by an encapsulation layer 55 made of SiO₂, as described above, and by a layer 56 of SiN. The SiO₂ layer is clearly visible and conformal (FIG. 6).

One advantage of the methods described is that they improve the temperature and humidity performance of image acquisition devices.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An optical device, comprising:
a support in which vias are formed;
a first electrode over the support;
an active layer of the first electrode and configured to absorb photons and transform absorbed photons into electron-hole pairs;
a second electrode over the active layer;
a conductive layer over the second electrode connecting the second electrode to one of the vias;
a microlens matrix over the conductive layer; and
an encapsulation layer arranged between the microlens matrix and the active layer;
wherein the encapsulation layer comprises a first portion having a first density and a second portion having a second density, the first portion of the encapsulation layer being arranged between the active layer and the second portion of the encapsulation layer, the first density being lower than the second density.

2. The device according to claim 1, wherein the encapsulation layer is based on silicon oxide.

3. The device according to claim 1, wherein the encapsulation layer is arranged between the active layer and the conductive layer.

4. The device according to claim 3, wherein the encapsulation layer covers the sides and a part of an upper face of the active layer.

5. The device according to claim 3, wherein the encapsulation layer is arranged between and in contact with two metal nitride layers.

6. The device of claim 1, wherein the encapsulation layer is arranged between the conductive layer and the microlens matrix.

7. The device according to claim 6, wherein the encapsulation layer is covered by a metal nitride layer.

8. The device according to claim 1, wherein said encapsulation layer comprises:
a first encapsulation layer arranged between the active layer and the conductive layer; and
a second encapsulation layer arranged between the conductive layer and the microlens matrix.

9. The device according to claim 1, wherein the conductive layer is made of aluminum.

10. The device according to claim 1, wherein the first density is between 2.05 and 2.13.

11. The device according to claim 1, wherein the second density is between 2.20 and 2.28.

12. The device according to claim 1, wherein the first portion of the encapsulation layer has a thickness between 50 and 250 nm.

13. The device according to claim 1, wherein the second portion of the encapsulation layer has a thickness of between 3 and 50 nm.

14. A method of manufacturing an optical device including: a support in which vias are formed; a first electrode over the support; an active layer of the first electrode and configured to absorb photons and transform absorbed photons into electron-hole pairs; a second electrode over the active layer; a conductive layer over the second electrode connecting the second electrode to one of the vias; a microlens matrix over the conductive layer; and an encapsulation layer arranged between the microlens matrix and the active layer;
the method comprising forming the encapsulation layer according to the following steps:
depositing a first precursor at a first deposition rate to form a first portion of the encapsulation layer having a first density; and
depositing a second precursor at a second deposition rate to form a second portion of the encapsulation layer having a second density;
wherein the first deposition rate is greater than the second deposition rate so that the first density is less than the second density.

15. The method according to claim 14, further comprising depositing the first portion of the encapsulation layer and the second portion of the encapsulation layer by PECVD at a temperature less than or equal to 150° C.

16. The method according to claim 14, wherein the first precursor and second precursor are silicon oxide precursors.

17. The method according to claim 16, wherein the first precursor and the second precursor are TEOS.

18. The method according to claim 14, wherein the first deposition rate is at least 5 times greater than the second deposition rate.
